(19) United States
(12) Patent Application Publication
(10) Pub. No.: US 2022/0045691 A1
(43) Pub. Date: Feb. 10, 2022

(54) SYSTEM AND METHOD TO COMPENSATE FOR FEEDBACK DELAYS IN DIGITAL CLASS-D MODULATORS

(71) Applicant: Analog Devices, Inc., Wilmington, MA (US)

(72) Inventors: Adam R. SPIRER, Westwood, MA (US); Abhishek BANDYOPADHYAY, Winchester, MA (US)

(73) Assignee: Analog Devices, Inc., Wilmington, MA (US)

(21) Appl. No.: 17/395,952

(22) Filed: Aug. 6, 2021

Related U.S. Application Data
(60) Provisional application No. 63/063,560, filed on Aug. 10, 2020.

(51) Int. Cl. H03M 3/00

(52) U.S. Cl. CPC H03M 3/33; H03M 3/416; H03M 3/368; H03M 3/436

(57) ABSTRACT

Systems and method for improving stability and performance in class-D modulators. In particular, a multi-cycle feedback network is positioned around a quantizer of a digital class-D amplifier. The multi-cycle feedback network allows the main class-D feedback loop to have multiple clock cycles of delay.

### CROSS-REFERENCE TO RELATED APPLICATIONS

This application is related to and claims the benefit of priority under 35 U.S.C. § 119(e) to U.S. Provisional Patent Application No. 63/063,560 entitled “SYSTEM AND METHOD TO COMPENSATE FOR FEEDBACK DELAYS IN DIGITAL CLASS-D MODULATORS” filed on Aug. 10, 2020, which is hereby incorporated by reference in its entirety.

### FIELD OF THE DISCLOSURE

The present invention relates to class D devices, and more specifically, to class D modulators.

### BACKGROUND

Devices, such as class AB drivers, modulators, converters, and amplifiers, can be used in audio devices such as speakers and headphone drivers. Most of these applications are battery driven, and thus power consumption is an important parameter. These devices also need to meet high performance in terms of signal-to-noise ratio (SNR) and total harmonic distortion (THD). Typically, these applications have different modes of operation, such that one mode can be performance optimized and another can be power consumption optimized.

Class D devices, such as drivers, modulators, converters, and amplifiers, can be used in audio devices such as speakers. In a conventional transistor amplifier, the output stage includes transistors that supply continuous output current. However, in conventional amplifiers, the output stage power dissipation is large. Class D amplifiers, dissipate much less power. Class D amplifiers use switches as amplifying devices. In particular, a class D amplifier output stage switches between the positive and negative power supplies so as to produce a train of voltage pulses. This reduces power dissipation because the output transistors have zero current when not switching, and have a low voltage when they are conducting current. Thus, class D devices have lower power dissipation, produce less heat, save circuit board space and cost, and (in portable systems) extend battery life.

### SUMMARY

Systems and method are provided for improving stability and performance in class-D modulators. In particular, a multi-cycle feedback network is positioned around a quantizer of a digital class-D amplifier. The multi-cycle feedback network allows the main class-D feedback loop to have multiple clock cycles of delay.

According to one aspect, an architecture for a class D modulator comprises an input line for receiving an input signal, a summer configured to subtract a feedback signal from the input signal and generate a summer output, a loop filter configured to receive the summer output and produce a filtered output, a quantizer configured to quantize the filtered output and output a quantized signal, a main feedback loop from the quantizer to the summer configured to filter the quantized signal to generate the feedback signal, and a quantizer feedback loop around the quantizer configured to add a delay to the quantized signal and feed a weighted delayed quantized signal back into the quantizer.

According to various implementations, the quantizer feedback loop includes an amplifier configured to apply a weight to the delayed quantized signal to generate the weighted delayed quantized signal. In some implementations, the quantizer feedback loop is a first quantizer feedback loop and further comprising a second quantizer feedback loop in parallel with the first quantizer feedback loop, wherein the second quantizer feedback loop is configured to add a second delay to the quantized signal. In some implementations, the weight is a first weight and wherein the second quantizer feedback loop includes a second amplifier configured to apply a second weight to the quantized signal. In some examples, the first weight is less than the second weight. In some examples, the weight has a value that is less than one, and wherein the weighted delayed quantized signal is smaller than the quantized signal

According to various implementations, the architecture includes a plurality of quantizer feedback loops around the quantizer. For examples, the architecture can include two, three, four, five, or more than five parallel quantizer feedback loops. In some implementations, the summer is a first summer and further comprising a second summer configured to add the filtered output and the weighted delayed quantized signal to generate a summed signal for input to the quantizer. In some implementations, the loop filter includes a plurality of integrators, wherein the filtered output includes a plurality of integrator outputs, and wherein each of the plurality of integrator outputs is summed at the second summer to generate the filtered output. In some implementations, the quantizer is one of a single-bit quantizer and a multi-bit quantizer. In various examples, the quantizer feedback loop includes one of a finite impulse response filter and an infinite impulse response filter.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

For a fuller understanding of the nature and advantages of the present invention, reference is made to the following detailed description of preferred embodiments and in connection with the accompanying drawings, in which:

FIG. 1 depicts a system architecture including an analog-to-digital converter for digital feedback;

FIGS. 2A-2F depict examples of system architectures for a modulator having feedback delay compensation, according to various embodiments of the disclosure;

FIGS. 3A-3B depict a root locus without delay, according to various embodiments of the disclosure;

FIGS. 3C-3D depict a root locus with single feedback delay, according to various embodiments of the disclosure;

FIGS. 4A-4B depict a root locus with feedback compensation for a single clock delay, according to various embodiments of the disclosure;

FIGS. 5A-5B depicts graphs showing the noise transfer function plots with and without feedback delay, according to various embodiments of the disclosure;

FIGS. 6A-6B depict a root locus with two delays, according to various embodiments of the disclosure;

FIG. 7 depicts a graph showing the noise transfer function without feedback delay and with two delays, according to various embodiments of the disclosure;

FIGS. 8A-8B depict a root locus with three delays, according to various embodiments of the disclosure; and

FIG. 9 is a block diagram of an example electrical device that may include one or more class D modulators, in accordance with various embodiments of the disclosure.

### DETAILED DESCRIPTION

In digital class D devices, the feedback analog-to-digital converter (ADC) is in a feedback loop for the modulator. The ADC is a low latency and complex ADC. A low latency ADC results in higher power consumption since the modulator runs at high speeds to achieve low latency. Systems and methods are provided for a modulator architecture in which the ADC runs at slower speeds, such that the modulator can be stabilized for more than 1 clock cycle delay. The power efficiency of the modulator is enhanced by running the ADC at a slower speed.

Systems and methods are provided for improving stability and performance in class-D modulators. In particular, a multi-cycle feedback network is positioned around a quantizer of a digital class-D amplifier. The multi-cycle feedback network allows the main class-D feedback loop to have multiple clock cycles of delay.

Generally, in a class-D amplifier with a digitally implemented loop filter, an ADC is used in the feedback path to convert the analog output back to digital for summation with the input. In some examples, the ADC has multiple clock cycles of latency in order to provide the noise performance dictated by the amplifier's specifications. However, the delays in the ADC add additional poles to the root locus, affecting closed-loop pole placement. This can negatively affect stability and result in large peaks in the noise transfer function (NTF). Systems and methods are provided to correct for the additional poles. In particular, for N cycles of delay in the ADC an Nth order filter can be placed in an additional digital feedback loop around the quantizer specifically. The additional digital feedback loop affects the additional poles such that the additional poles have a lesser impact on the placement of the other closed-loop poles. This results in an NTF that much more closely resembles that of the system without any delays in the feedback path. In some examples, for instance for larger N, the additional feedback loop causes an otherwise unstable loop to become stable.

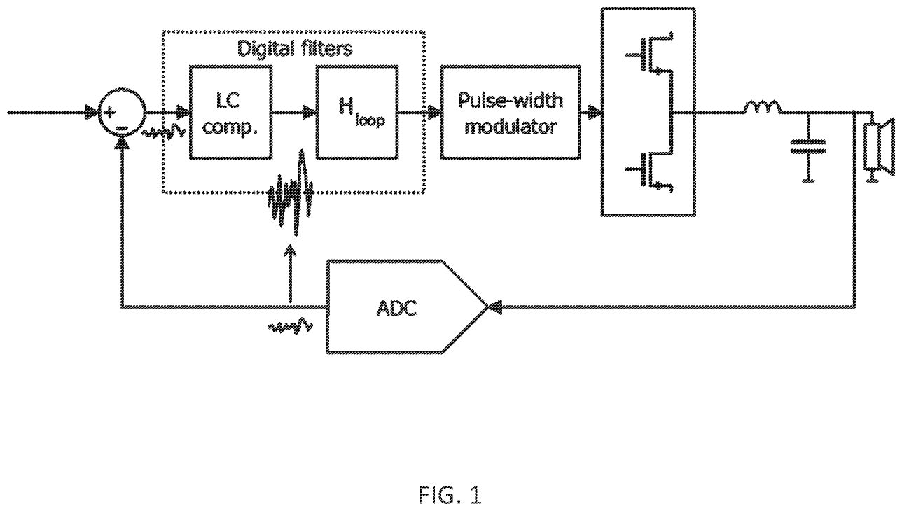

FIG. 1 shows a traditional modulator having an ADC for digital feedback. The modulator shown in FIG. 1 is a sigma delta loop in the digital domain. The modulator 100 includes digital filters, a pulse width modulator, a class D output, and some filtering for the class D output. The feedback loop includes an analog-to-digital converter that digitizes the output signal and feeds back a digital representation of the output signal. The output is fed back with no latency for the next clock cycle of the modulator. The feedback ADC is a high resolution ADC without latency and with low out-of-band noise. Thus, the ADC is power hungry, and in some examples, the ADC is an 800 mW delta sigma ADC having a 3 MHz bandwidth. In contrast, a sigma-delta modulator of the current invention uses ˜1.5 mW. Thus, systems and methods are needed for a low power feedback ADC for a sigma-delta modulator.

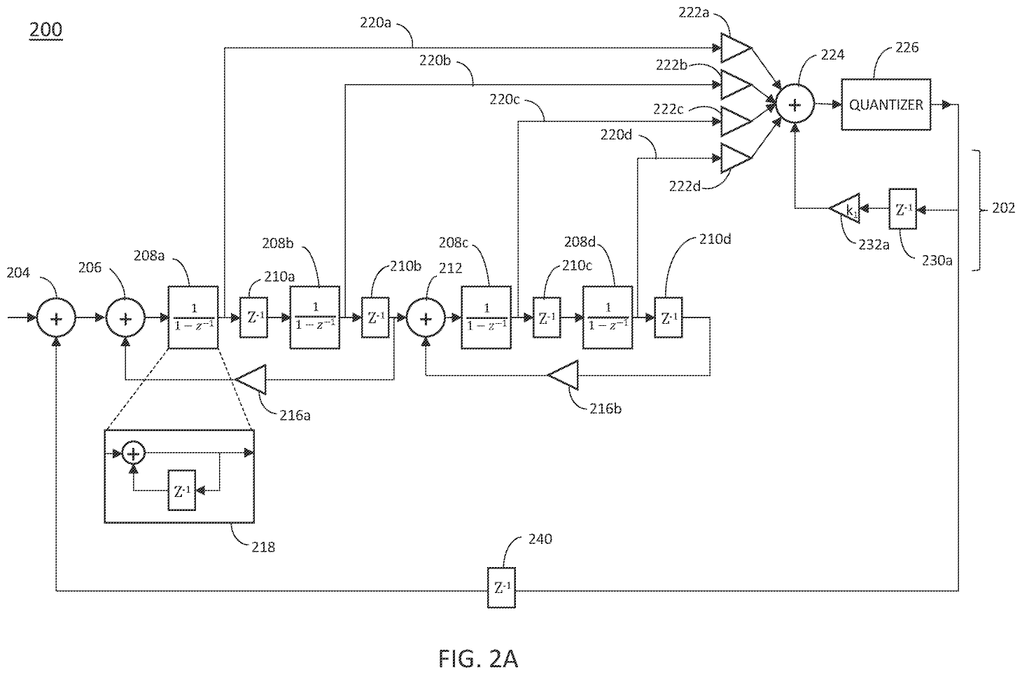

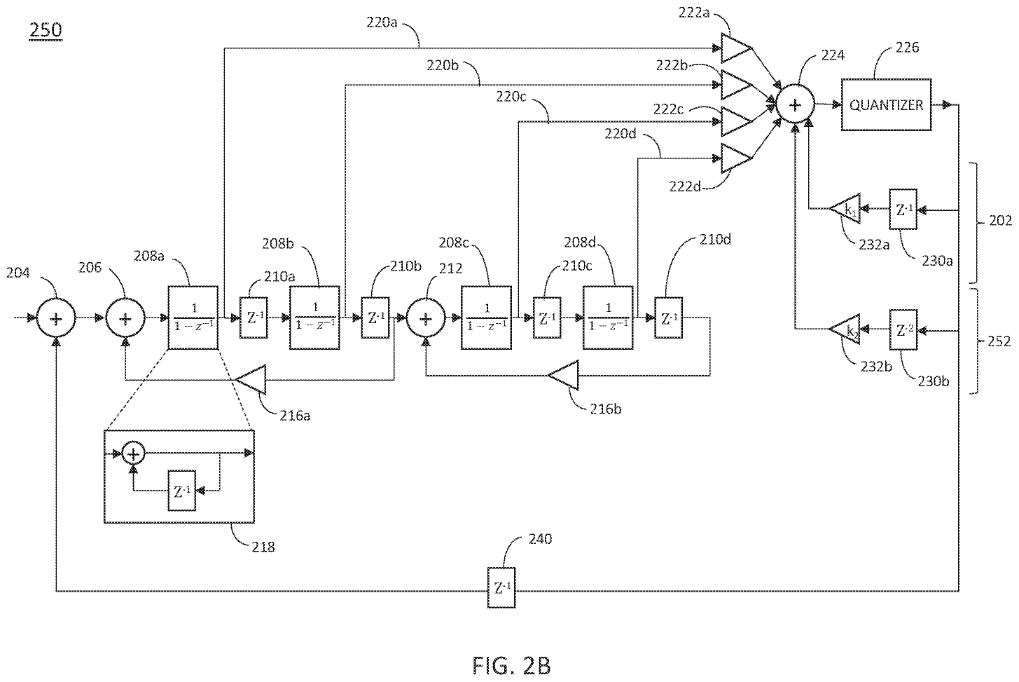

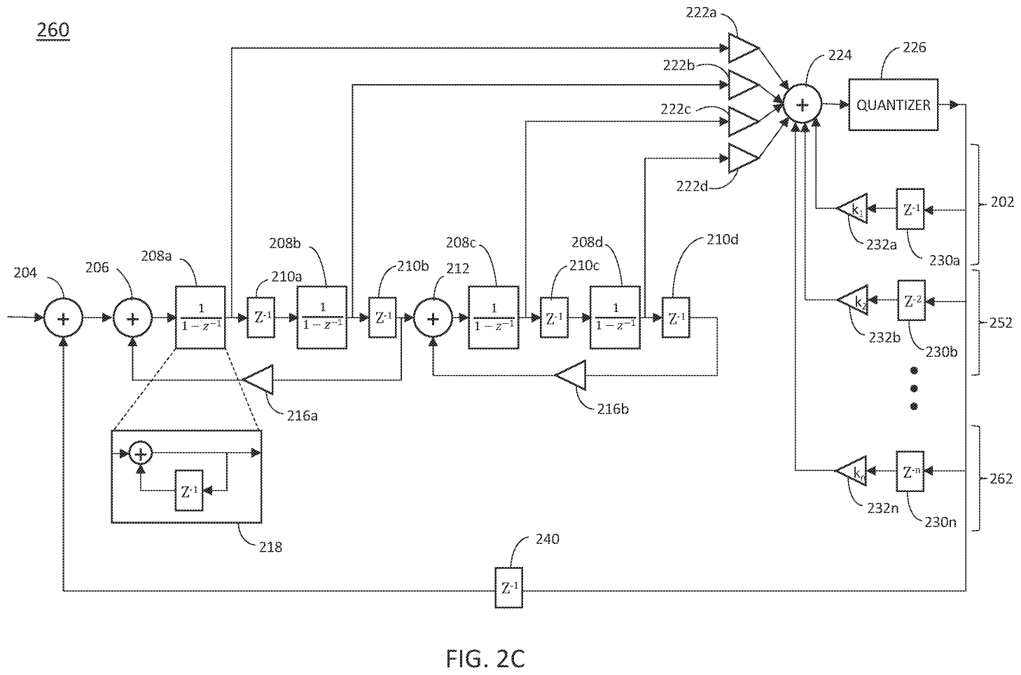

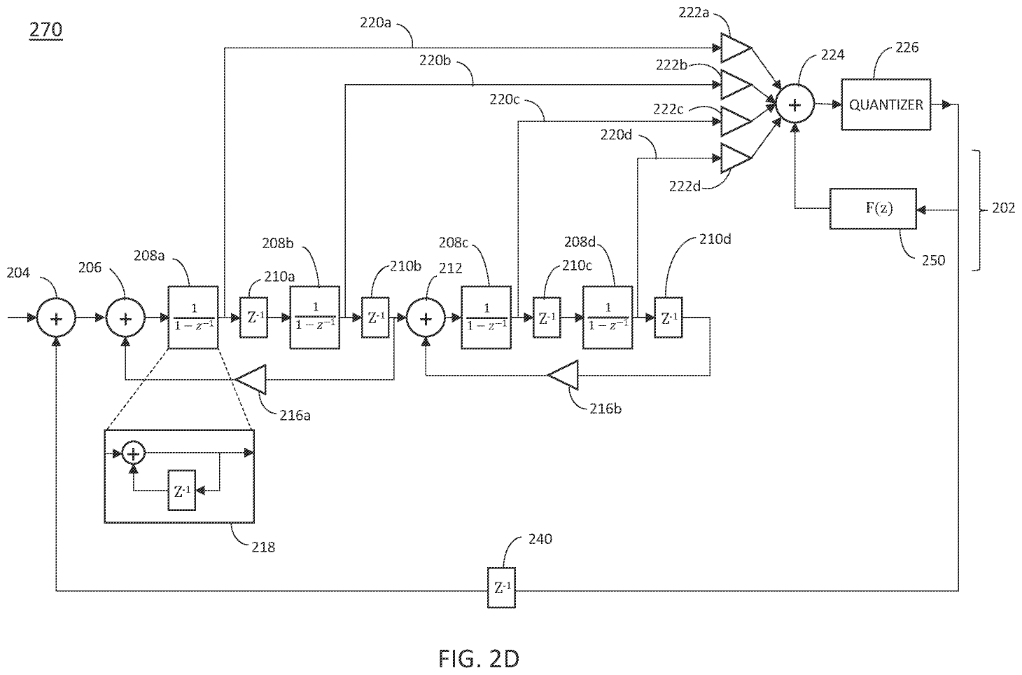

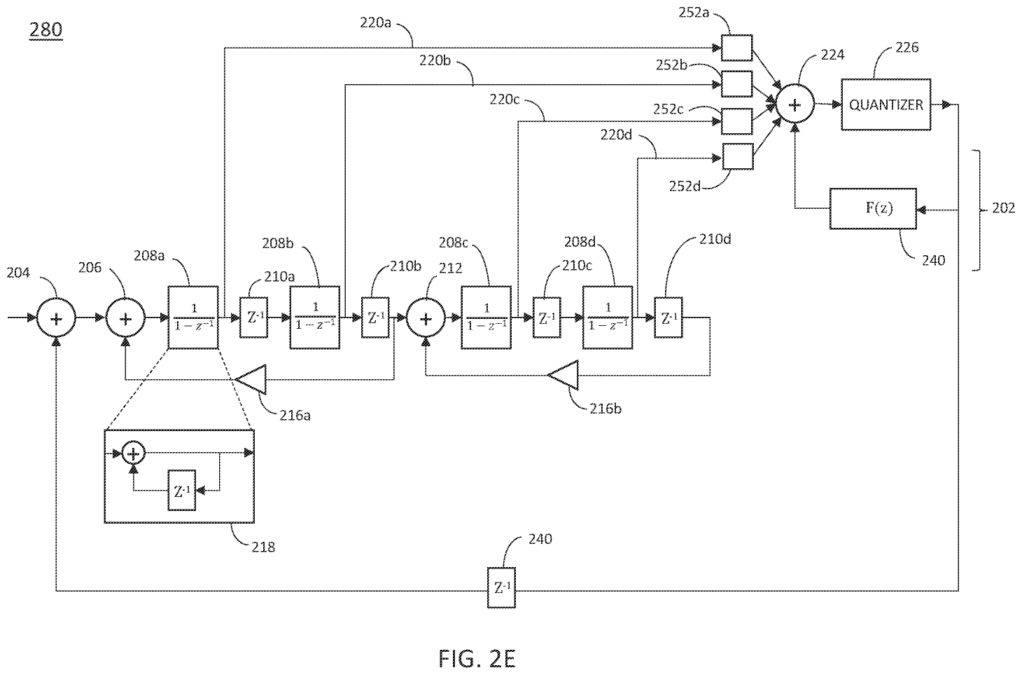

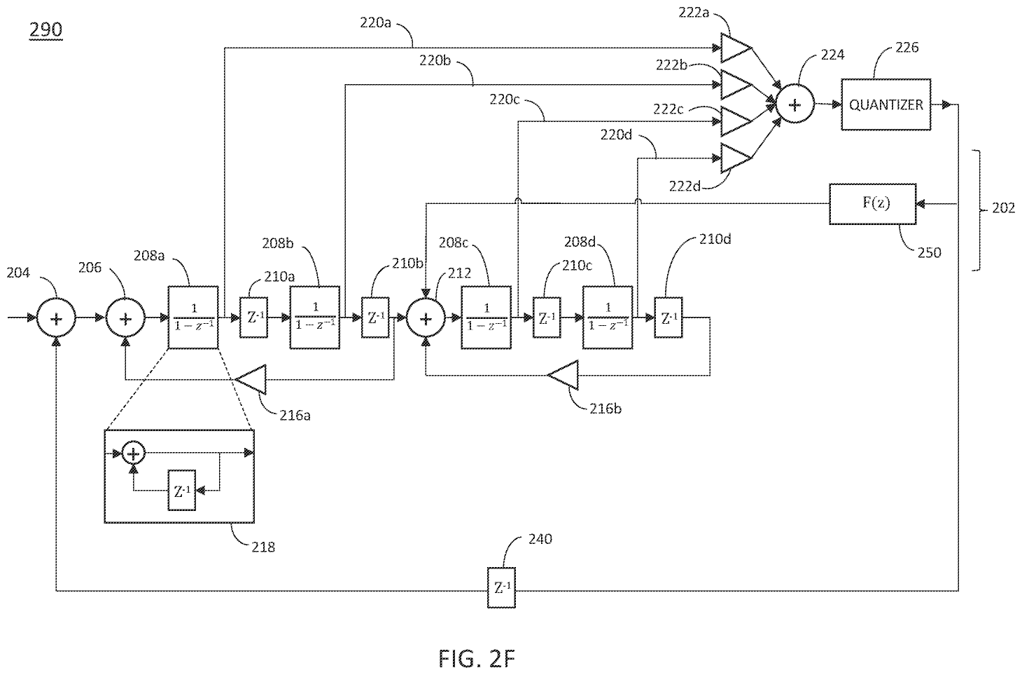

FIG. 2A shows an analog class D modulator 200 with a quantizer feedback loop 202, according to various embodiments of the disclosure. The modulator 200 receives an analog input signal at a first summer 204, where a main feedback loop signal is subtracted from the analog input signal. The output from the first summer 204 is then processed by a loop filter. The loop filter includes first 208a, 210a, second 208b, 210b, third 208c, 210c, and fourth 208d, 210d integrators, and second 206 and third 212 summers. The output from each of the first 208a, second 208b, third 208c, and fourth 208d first parts of the integrators is input to a respective first 222a, second 222b, third 222c, or fourth 222d amplifier, via a respective feedforward line 220a, 220b, 220c, 220d. In some examples, the feedforward lines 220a, 220b, 220c, 220d include a filter, such as an IIR filter or an FIR filter. In some examples, the feedforward lines 220a, 220b, 220c, 220d include a gain. The first 222a, second 222b, third 222c, or fourth 222d amplifier outputs are added at a fourth summer 224, and the fourth summer 224 output is input to the quantizer 226.

Additionally, the loop filter includes two feedback loops. The first feedback loop feeds the output from the second part of the second integrator 210b back to the second summer 206. The first feedback loop includes a fifth amplifier 216a, which amplifies the signal, and the fifth amplifier 216a output is input to the second summer 206. At the second summer 206, the amplified feedback signal is added to the output from the first summer 204 and input to the first part of the first integrator 208a. The second feedback loop similarly feeds the output from the second part of the fourth integrator 210d back to the third summer 212. The second feedback loop includes a sixth amplifier 216b, which amplifies the signal, and the sixth amplifier 216b output is input to the third summer 212. At the third summer 212, the amplified feedback signal is added to the output from the second part of the second integrator 210b and input to the first part of the third integrator 208c.

The quantizer feedback loop 202 provides feedback around the quantizer 226. The feedback loop 202 around the quantizer 226 includes a filter. The quantizer feedback loop 202 takes the quantizer 226 output, filters it, at feeds it back to the quantizer 226 input. In some examples, the filter is a finite impulse response filter and, in some examples, the filter is an infinite impulse response filter. The feedforward paths 222a-222d can be either gain blocks or filters, which become IIR filters. In some examples, the input to the filter 230a is the quantizer 226 output. In some examples, the input to the filter 230a is the quantizer 226 input. In some examples, the input to the filter 230a is the summer 224 output.

The quantizer feedback loop 202 takes the quantizer 226 output and multiplies it by the gain factor k₁ at a first feedback amplifier 232a and feeds it back to the fourth summer 224, where it is fed directly back to the quantizer 226. The quantizer feedback 202 loop has a gain of ‘k₁’, and is faster than the outer main feedback loop that includes the delay block 240. In one example, the quantizer feedback loop 202 has a one clock cycle delay at the first feedback delay block 230a; z⁻¹ can have up to a one clock cycle delay. Adding the delay at the first feedback delay block 230a in the quantizer feedback loop 202 corrects for the ADC delay. In particular, z⁻¹ allows for a delay of one sample in the ADC. In some examples, the gain factor k₁ at the first feedback amplifier 232a is less than one. In various examples, the gain factor ₁k is 0.5, 0.4, 0.03, 0.25, 0.2, 0.15, 0.125, 0.1, 0.075, 0.0625, or 0.05. The feedback loop 202 allows for error correction in the quantizer 226.

In some implementations, the digital-only/quantizer output is used directly for the quantizer feedback loop 202, and the quantizer feedback loop 202 does not use the power stage output. In contrast, the main outer feedback loop with the outer delay block 240 uses the power stage output. Thus, the two feedback loops are different. In some examples, the feedback delay itself causes extra pulses, thereby minimizing increased pulse density.

FIG. 2B shows an analog class D modulator 250 with two quantizer feedback loops, according to various embodiments of the disclosure. In particular, the modulator 250 includes the first quantizer feedback loop 202, as described above with respect to FIG. 2A, and a second quantizer feedback loop 252. Like the first quantizer feedback loop 202, the second quantizer feedback loop 252 provides feedback around the quantizer 226, in parallel with the first quantizer feedback loop 202. In some examples, the input to the filter 230b is the quantizer 226 output. In some examples, the input to the filter 230b is the quantizer 226 input. In some examples, the input to the filter 230b is the summer 224 output.

The feedback loop 252 around the quantizer 226 includes a second feedback delay block 230b and a second feedback amplifier 232b, and the quantizer feedback loop 252 takes the quantizer 226 output, filters it, at feeds it back to the quantizer 226 input. In particular, the second quantizer feedback loop 252 takes the quantizer 226 output and multiplies it by the gain factor k₂ and feeds it back to the fourth summer 224, where it is fed directly back to the quantizer 226. The second feedback amplifier has a gain of ‘k₂’. In one example, there is a two clock cycle delay; that is, the second feedback delay block 230b has a z⁻² delay, which can be a two clock cycle delay. Adding the second delay in the second quantizer feedback loop 252 allows for additional ADC latency. In particular, z⁻² allows for a delay of two samples in the ADC. In some examples, the gain factor k₂ is less than one. In various examples, the gain factor k₂ is 0.5, 0.4, 0.03, 0.25, 0.2, 0.15, 0.125, 0.1, 0.075, 0.0625, or 0.05. In some examples, k₁ and k₂ have different values. In one example, k₁ is 0.125 and k₂ is 0.25. The second quantizer feedback loop 252 allows for additional error correction in the quantizer 226.

In another example, more filtering can be added at k and the outer feedback loop can have be z⁻³, z⁻⁴, . . . z⁻ⁿ. In various examples, this slows the feedback loop down more than one clock cycle. In some examples, the quantizer feedback loop filter is one of a finite impulse response (FIR) filter and an infinite impulse response (IIR) filter.

FIG. 2C shows an analog class D modulator 260 with multiple quantizer feedback loops, according to various embodiments of the disclosure. In particular, the modulator 250 includes the first quantizer feedback loop 202, as described above with respect to FIG. 2A, the second quantizer feedback loop 252, as described above with respect to FIG. 2B, and illustrates that any number of additional quantizer feedback loops 262 can be added in parallel the first 202 and second 252 feedback loops. In some examples, the input to the filter 230c is the quantizer 226 output. In some examples, the input to the filter 230c is the quantizer 226 input. In some examples, the input to the filter 230c is the summer 224 output.

The third quantizer feedback loop 262 around the quantizer 226 includes a third feedback delay block 230c and a third feedback amplifier 232c, and the third quantizer feedback loop 262 takes the quantizer 226 output, filters it, at feeds it back to the quantizer 226 input. As illustrated in FIG. 2C, the third quantizer feedback loop 262 is the nth quantizer feedback loop, and there may be four, five, six, or more quantizer feedback loops. The third quantizer feedback loop 262 takes the quantizer 226 output and multiplies it by the gain factor kₙ and feeds it back to the fourth summer 224, where it is fed directly back to the quantizer 226. That is, the third feedback amplifier 232n has a gain of ‘kₙ’. In one example, there is a n clock cycle delay; that is, the third feedback delay block 230n has a z⁻ⁿ delay, which can be a n clock cycle delay. Adding the third delay in the third quantizer feedback loop 252 allows for additional ADC latency. In particular, z⁻ⁿ allows for a delay of n samples in the ADC. In some examples, the gain factor kₙ is less than one. In various examples, the gain factor kₙ is 0.5, 0.4, 0.03, 0.25, 0.2, 0.15, 0.125, 0.1, 0.075, 0.0625, 0.05, or less than 0.05. In some examples, k₁, k₂, . . . kₙ have different values. In one example, there are three feedback loops, and k₁ is 0.0625, k₂ is 0.125, and k₃ is 0.25. Additional quantizer feedback loops 262 allow for additional error correction in the quantizer 226.

FIG. 2D shows an analog class D modulator 270 with quantizer feedback loops represented by a filter 250, according to various embodiments of the disclosure. In various examples, FIGS. 2A-2C are implementations of FIG. 2D, in which one or more of the filters 230a, 230b, 230c are represented by the filter 250. In some examples, the input to the filter 250 comes from the output of the quantizer 226. In some examples, the input to the filter 250 comes from the output of the summer 224. In various implementations, filter inputs from the quantizer 226 or the summer 224 are used for performing finite impulse response (FIR) filtering. When the filter F(z) 250 is order N, then N samples delay are provided by the filter 250.

FIG. 2E shows an analog class D modulator 280 with quantizer feedback loops and feedforward filtering blocks 252a-252d, according to various embodiments of the disclosure. The feedforward filtering blocks 252a, 252b, 252c, 252d filter the integrator outputs along the feedforward lines 220a, 220b, 220c, 220d. In some examples, the feedforward filtering blocks 252a, 252b, 252c, 252d are used for infinite impulse response (IIR) filtering, and replace the gain blocks of FIGS. 2A-2D.

FIG. 2F shows an analog class D modulator 290 with quantizer feedback loops represented by a filter 250, according to various embodiments of the disclosure. As shown in FIG. 2F, the output of the filter 250 is input to the third summer 212. In some examples, the output of the filter 250 is input to the second summer 206. In some examples, the output of the filter 250 is input to the first summer 204. In some examples, the input to the filter 250 comes from the output of the quantizer 226. In some examples, the input to the filter 250 comes from the output of the summer 224. In various implementations, filter inputs from the quantizer 226 or the summer 224 are used for performing finite impulse response (FIR) filtering. When the filter F(z) 250 is order N, then N samples delay are provided by the filter 250.

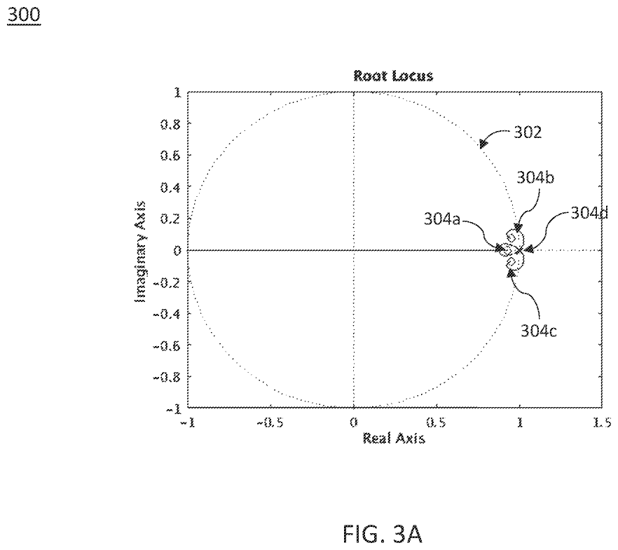

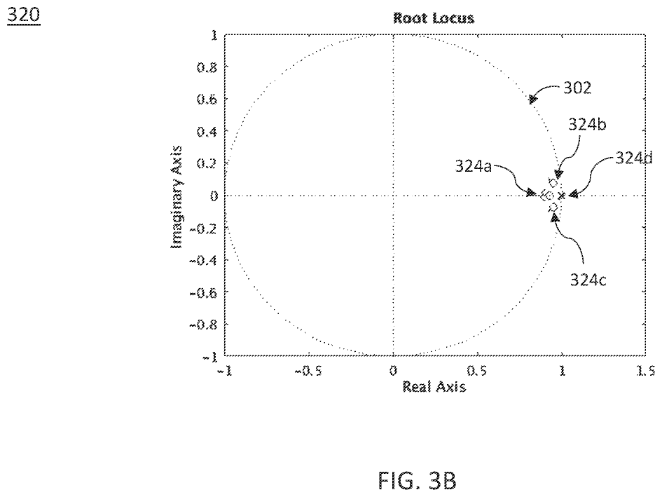

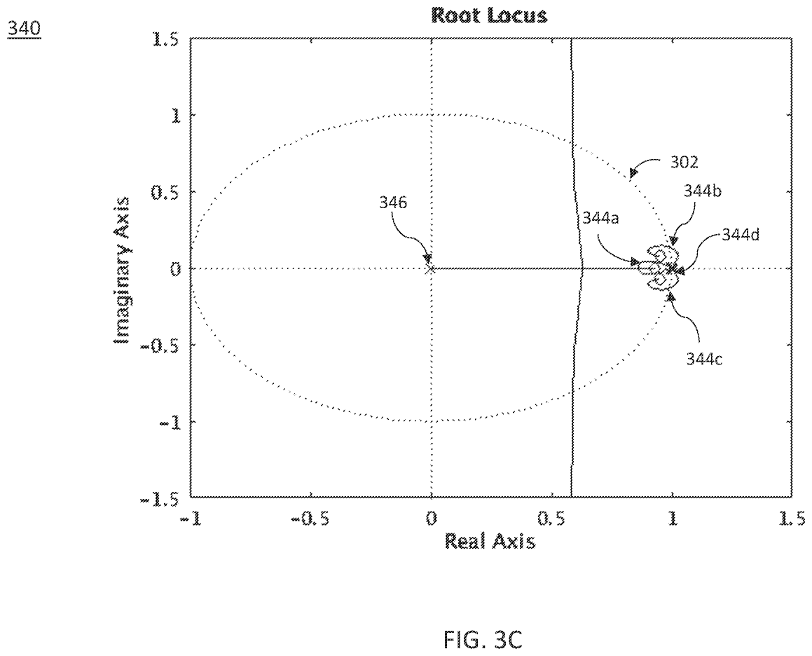

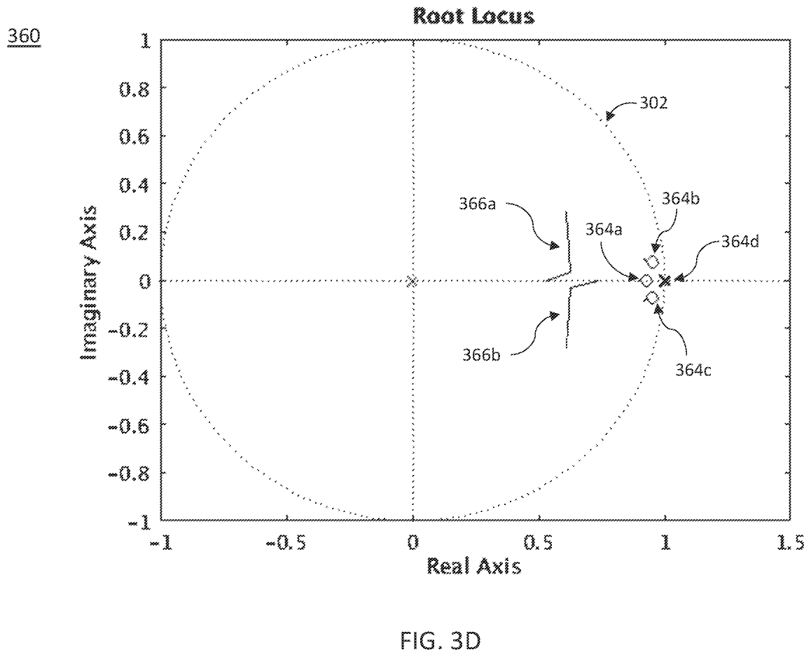

Sigma delta modulator performance is represented by the signal transfer function (STF) and the noise transfer function (NTF). The STF is a measure of the output signal relative to the input signal. The NTF is a function of the output error relative to the input error and indicates the error introduced by the quantizer. From a frequency domain perspective, the root locus can be analyzed to graphically examine how the modulator input and output change with variations in quantizer feedback. FIGS. 3A-3B depict a root locus with no delay in the main feedback loop, according to various embodiments of the disclosure. FIG. 3A shows a root locus graph 300 including a unity circle 302, and root locus plots 304a, 304b, 304c, 304d which vary slightly, since the NTF varies depending on the feedback. FIG. 3B shows a root locus graph 320 including root locus plots 324a 324b, 324c, 324d showing closed loop poles in the root locus at expected locations with unity gain.

FIGS. 3C-3D depict a root locus with single feedback delay added in the main feedback loop for the feedback ADC, according to various embodiments of the disclosure. As shown in FIG. 3C, there is an additional pole 326 from the feedback delay. Adding the feedback delay to the main feedback loop creates the additional pole 346 pole, which increases positively to infinity and negatively to infinity. The additional pole 346 also affects where the rest of the poles 344a, 344b, 344c, 344d move when the loop is closed, such that the NTF changes. This creates instability in terms of frequency and loop oscillating. In general, this results in higher gain and peaks in the NTF. A side effect of this is drastically increased idle pulse density. FIG. 3D shows two closed loop poles 366a, 366b, which moved out of elliptic arrangement at unity feedback, causing peaking.

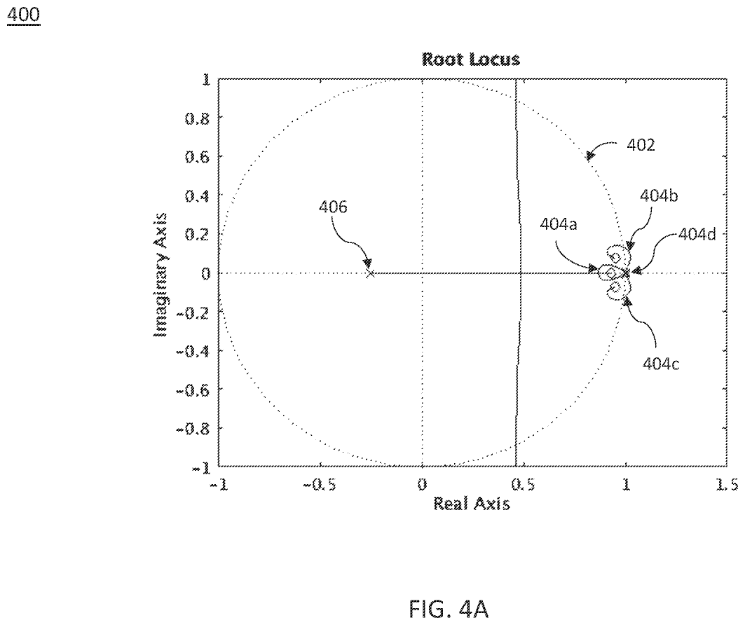

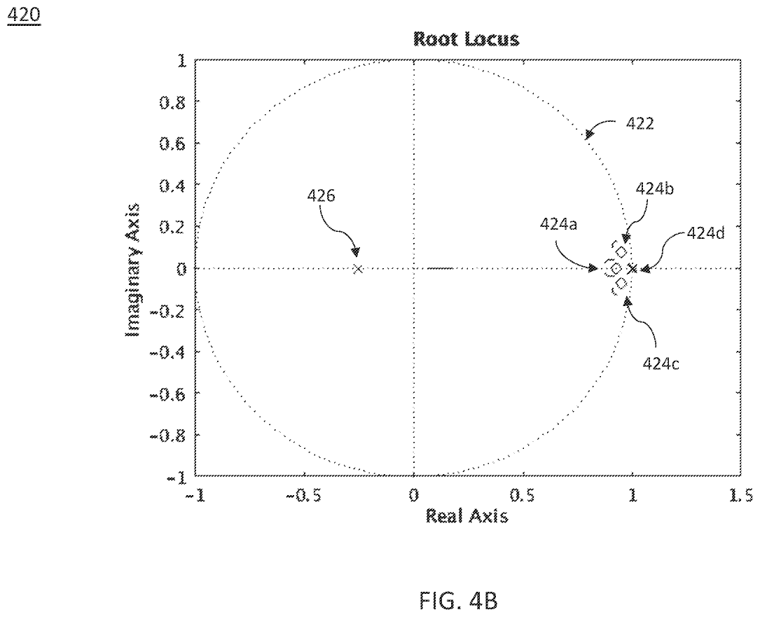

FIGS. 4A-4B depict a root locus for a sigma-delta modulator with quantizer feedback compensation, according to various embodiments of the disclosure. In particular, FIGS. 4A-4B depict a root locus for a sigma-delta modulator with a single quantizer feedback loop, as depicted, for example, in FIG. 2A, and thus a single clock delay. Adding the quantizer feedback loop changes the root locus. As shown in FIG. 4A, the additional pole 406 from the feedback delay is shifted further away from the other poles 404a, 404b, 404c, thereby minimizing the effect of the additional pole 406 on the poles 404a, 404b, 404c, 404d. The additional pole 406 is shifted to the left. The additional pole 406 stays on the real axis.

As shown in FIG. 4B, at unity feedback, the closed-loop noise transfer function pole is back where expected. The four poles 424a, 424b, 424c, 424d are at expected locations for unity feedback, and the modulator is stabilized. The additional pole 426 is on the real axis, as described above with respect to FIG. 4A, with no peaking, and a small effect on gain.

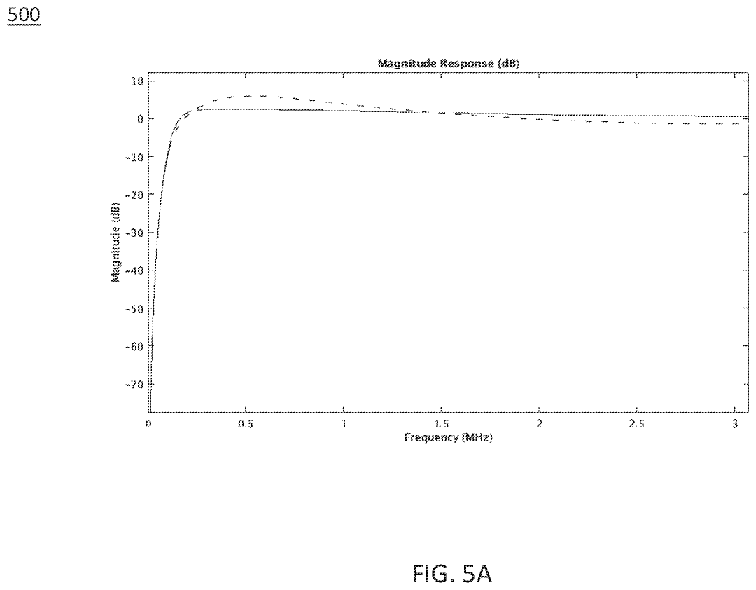

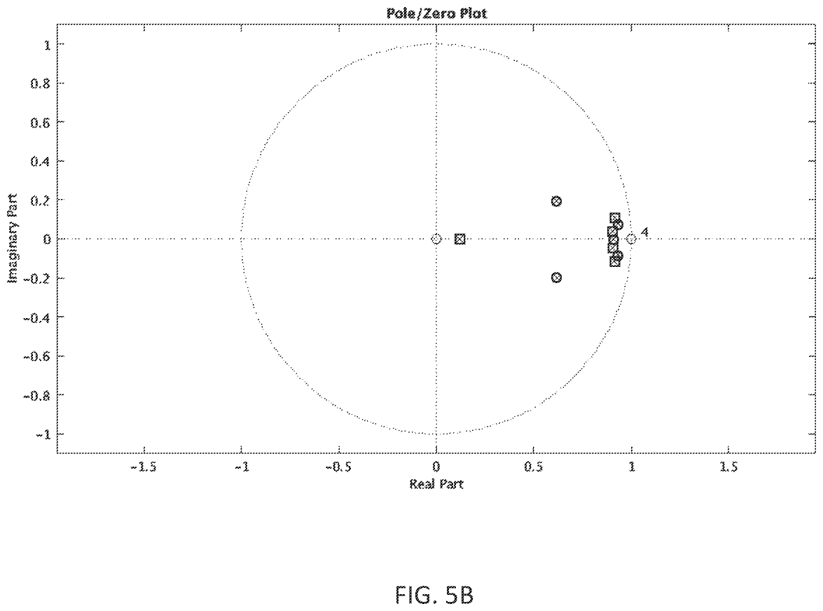

FIG. 5A depicts a graph showing the frequency response of the noise transfer function with and without feedback delay, according to various embodiments of the disclosure. The dashed line shows the frequency response of noise transfer function before the addition of the quantizer feedback loop. Without the quantizer feedback loop, there is peaking in the noise transfer function, and around this peak frequency, there will be oscillation in the output due to quantizer delay. In particular, in trying to correct for the quantizer delay results in a swinging oscillation effect. In contrast, the solid line shows the frequency response of the noise transfer function after the addition of the quantizer feedback loop. The peak frequency is flattened out, and largely eliminating any output oscillation effect.

FIG. 5B shows corresponding pole/zero plots for the noise transfer functions shown in FIG. 5A. In particular, the circled x's correspond to measurements for the noise transfer function before the addition of the quantizer feedback loop, as illustrated by the dashed line in FIG. 5A. The squares with x's correspond to measurements of the noise transfer function after the addition of the quantizer feedback loop, as illustrated by the solid line in FIG. 5A.

In various implementations, more than one clock cycle delay is added to the feedback path ADC. In particular, as discussed above with respect to FIGS. 2B and 2C, the quantizer feedback compensation loop is extended to include multiple parallel quantizer feedback compensation loops, which can be represented as a weighted sum of previous quantizer outputs. Thus, ‘k’ from FIG. 2A becomes the transfer function K(z), which includes k₁, k₂, . . . kₙ. Additionally, the NTF is:

$$\frac{1}{( 1 + {z}^{- n} H ( z ) + K ( z ) )}$$

where H(z) is the loop filter transfer function, and K(z) is the feedback to the quantizer directly. The loop filter transfer function H(z) is the transfer function for the integrators, the summer, and the resonators.

In various examples, the delays are managed between the two branches. The block diagram in FIG. 2A shows a delay-free H(z) and a single delay in the quantizer. In some examples, the circuit shown in FIG. 2A avoids glitches on quantizer output. In some implementations, the delay is incorporated by including the delay in ‘N’ (e.g., one delay in the ADC is N=2) and includes a z⁻¹ in K(z). Thus, the quantizer delay is considered when computing the root locus, and a delay-free loop is not inadvertently created by the K(z) loop.

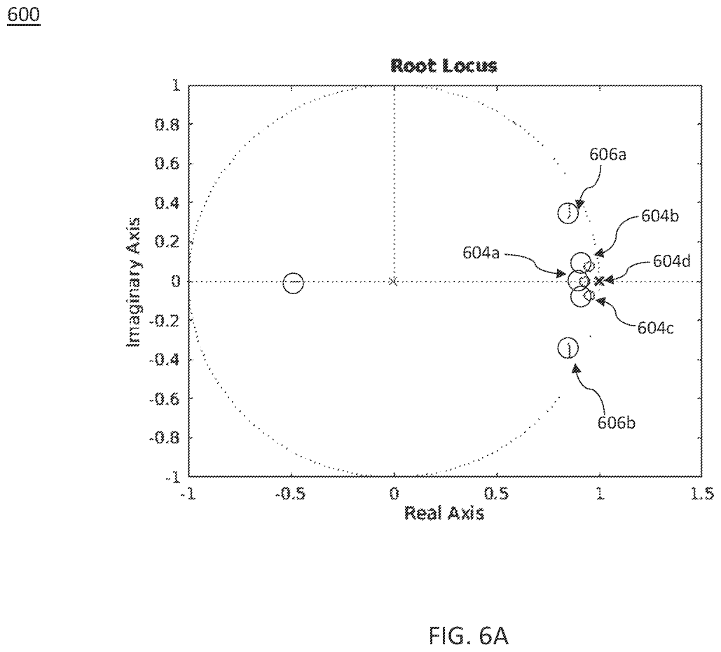

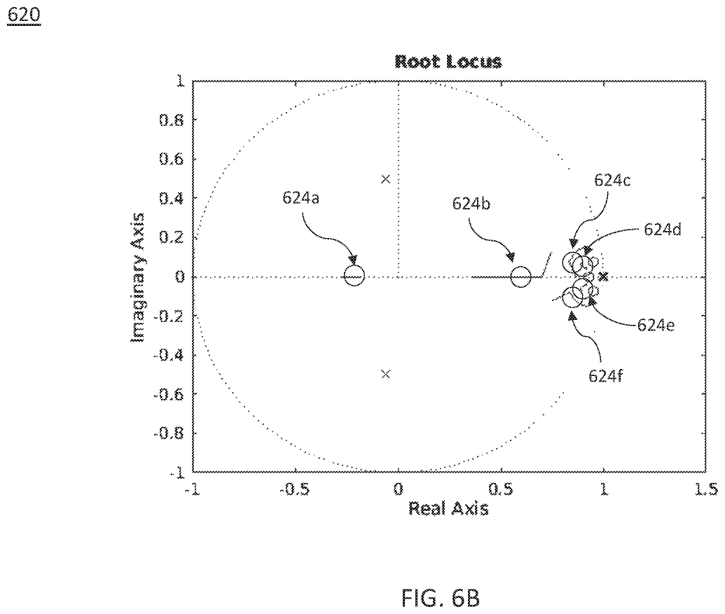

FIGS. 6A-6B are before and after graphs showing root locus with two clock cycle delays in the ADC feedback, according to various embodiments of the disclosure. In particular, FIG. 6A shows approximate closed-loop pole locations 604a-604d before K(z) correction. Note that the poles 604a-604d are very close to the unit circle. Additionally, FIG. 6A shows the large peaks 606a, 606b in the noise transfer function.

FIG. 6B shows approximate closed-loop pole locations after K(z) correction. In the example shown in FIG. 6B, the K(z) weighting is [0.125, 0.25]. That is, k₁=0.125 and k₂=0.25. Thus, the previous quantizer output (z−1) is weighted by 0.125, which the quantizer output before the previous quantizer output (z−2) is weighted by 0.25, and after this weighting, the two outputs are fed back to the quantizer (via a summer that outputs the quantizer input). After these K(z) weightings with the two previous outputs, the closed-loop poles 626a-626f move away from the edge of the unit circle to a more stable location.

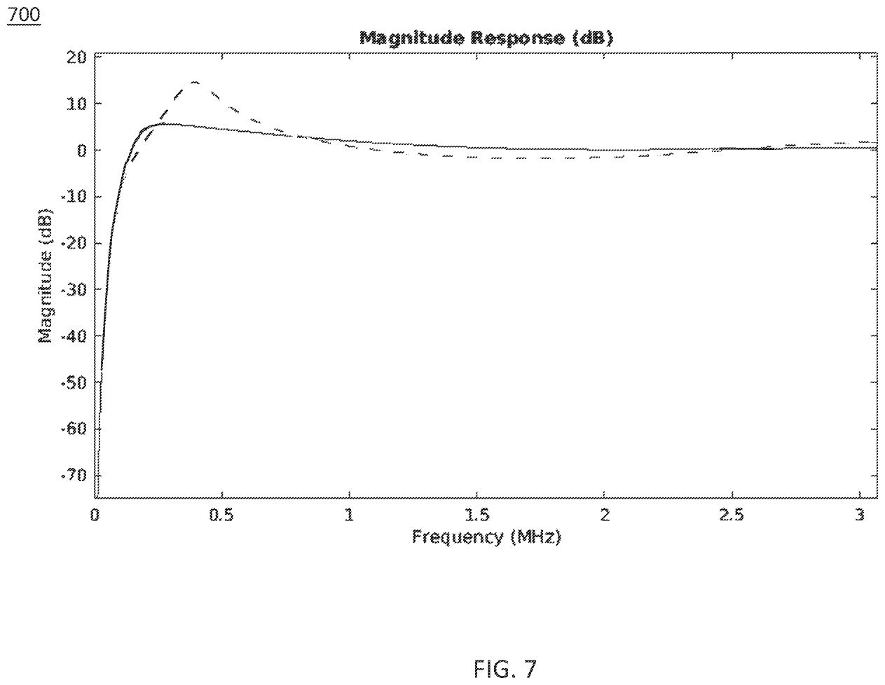

FIG. 7 is a graph 700 showing the noise transfer function before and after the addition of the quantizer feedback loop with K(z) correction, and 2 clock cycle delays in the ADC feedback. In particular, the dashed line shows the peaking in the noise transfer function, which is a result of the poles being so close to the unit circle. The solid line shows the corrected noise transfer function after the addition of two parallel quantizer feedback loops. While there is still a small amount of peaking, it is drastically corrected as compared to the dashed line, and the modulator is much more stable.

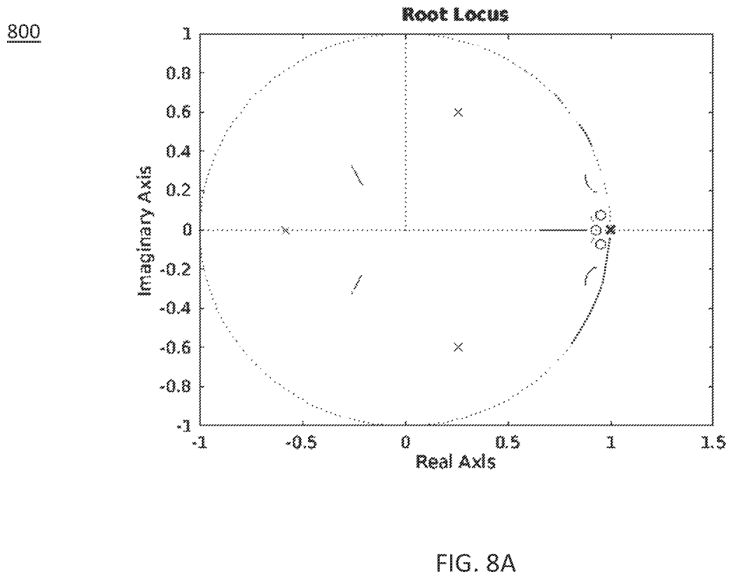

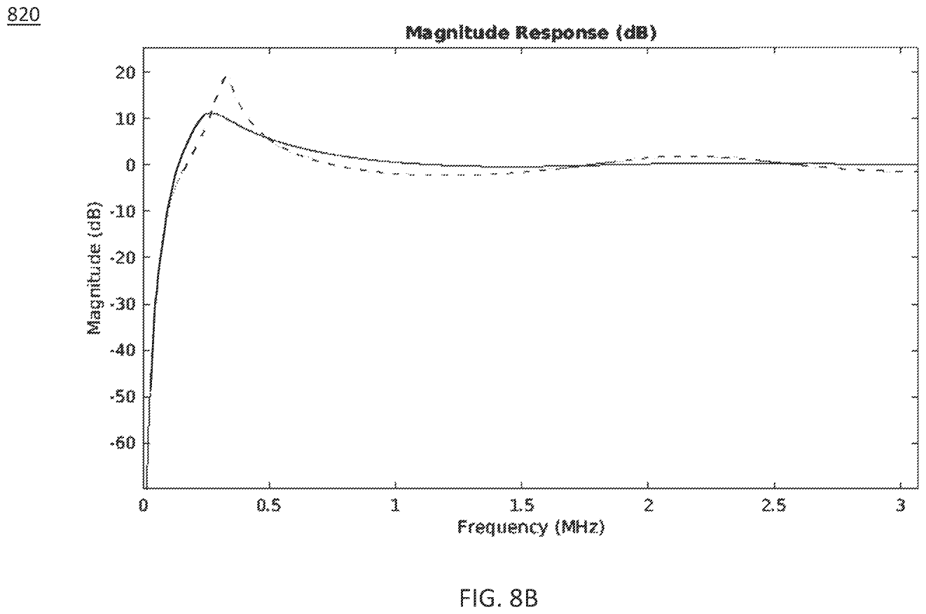

In some implementations, three delays can be added to the feedback path. However, without K(z) correction, three delays in the feedback path produces an unstable loop without K(z) correction. Adding K(z) correction as described herein makes the loop stable. In one example, shown in FIGS. 8A-8B, the K(z) weighting is [0.0625, 0.125, 0.25]. That is, the previous quantizer output is weighted at 0.0625 (k₁=0.0625) and then added back to the quantizer input, the output before the previous quantizer output is weighted at 0.125 (k₂=0.125) and then added back to the quantizer input, and the output before that is weighted at 0.25 (k₃=0.25) and then added back to the quantizer input. In other examples, other weighting coefficients are used. FIG. 8A shows root locus closed-loop pole locations after correction with the feedback loop. The short lines indicate rough placement with unity feedback. FIG. 8B shows the noise transfer function with pre- and post-K(z) correction. The dashed line shows the noise transfer function before correction with the quantizer feedback loops, and the solid line shows the noise transfer function after correction with the quantizer feedback loops. According to some examples, pre-correction, the system is not stable. Post-correction, the system is stable, despite minimal peaking.

In some implementations, the stability and/or headroom of the circuit can lose a few dB at very high output levels. According to various examples, integrators reach wraparound much faster when there is feedback delay. Thus, calculating integrator saturation while including the delay limits the output level. However, integrator saturation points based on the loop without feedback delay show that the integrators are saturated at lower values for the same input level. The integrators can be re-optimized after adding the feedback loop with the filter around the quantizer. According to various examples, the circuit can have better in-band performance even when the delay is added back in.

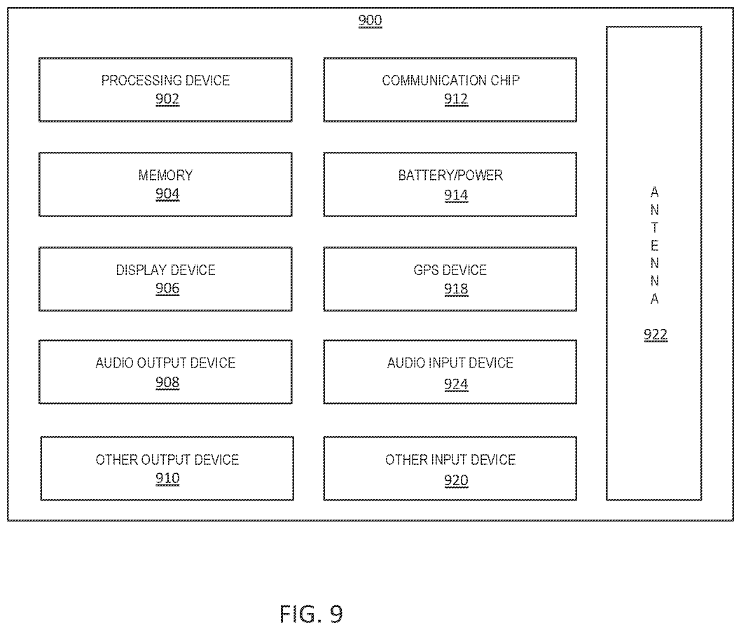

FIG. 9 is a block diagram of an example electrical device 900 that may include one or more class D drivers, in accordance with any of the embodiments disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards. In some embodiments, some or all of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include a processing device 902 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 900 may include a memory 904, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 904 may include memory that shares a die with the processing device 902. This memory may be used as cache memory and may include embedded dynamic random access memory (eDRAM) or spin transfer torque magnetic random access memory (STT-MRAM).

In some embodiments, the electrical device 900 may include a communication chip 912 (e.g., one or more communication chips). For example, the communication chip 912 may be configured for managing wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication chip 912 may manage wired communications, such as electrical, optical, or any other suitable communication protocols (e.g., the Ethernet). As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as global positioning system (GPS), EDGE, GPRS, CDMA, WiMAX, LTE, EV-DO, or others. In some embodiments, a first communication chip 912 may be dedicated to wireless communications, and a second communication chip 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include any visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any device that generates an audible indicator, such as speakers, headsets, or earbuds.

The electrical device 900 may include an audio input device 924 (or corresponding interface circuitry, as discussed above). The audio input device 924 may include any device that generates a signal representative of a sound, such as microphones, microphone arrays, or digital instruments (e.g., instruments having a musical instrument digital interface (MIDI) output).

The electrical device 900 may include a GPS device 910 (or corresponding interface circuitry, as discussed above). The GPS device 910 may be in communication with a satellite-based system and may receive a location of the electrical device 900, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 900 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 900 may be any other electronic device that processes data.

### Select Examples

Example 1 provides an architecture for a class D modulator, comprising: an input line for receiving an input signal; a summer configured to subtract a feedback signal from the input signal and generate a summer output; a loop filter configured to receive the summer output and produce a filtered output; a quantizer configured to quantize the filtered output and output a quantized signal; a main feedback loop from the quantizer to the summer configured to filter the quantized signal to generate the feedback signal; and a quantizer feedback loop around the quantizer including a first filter, configured to generate a filtered quantized signal, wherein the filtered quantized signal is added back into the quantizer.

Example 2 provides an architecture according to one or more of the preceding and/or following examples, wherein the quantizer feedback loop includes an amplifier configured to apply a weight to the quantized signal to generate the filtered quantized signal.

Example 3 provides an architecture according to one or more of the preceding and/or following examples, wherein the quantizer feedback loop is a first quantizer feedback loop and the filtered quantized signal is a first filtered quantized signal, and further comprising a second quantizer feedback loop in parallel with the first quantizer feedback loop, wherein the second quantizer feedback loop is configured to generate a second filtered quantized signal, and wherein the second filtered quantized signal is added back to the quantizer.

Example 4 provides an architecture according to one or more of the preceding and/or following examples, wherein the weight is a first weight and wherein the second quantizer feedback loop includes a second amplifier configured to apply a second weight to the quantized signal to generate the second filtered quantized signal.

Example 5 provides an architecture according to one or more of the preceding and/or following examples, wherein the first weight is less than the second weight.

Example 6 provides an architecture according to one or more of the preceding and/or following examples, wherein the weight has a value that is less than one, and wherein the filtered quantized signal is smaller than the quantized signal.

Example 7 provides an architecture according to one or more of the preceding and/or following examples, further comprising a plurality of quantizer feedback loops around the quantizer.

Example 8 provides an architecture according to one or more of the preceding and/or following examples, wherein the summer is a first summer and further comprising a second summer configured to add the filtered output and the filtered quantized signal to generate a summed signal for input to the quantizer.

Example 9 provides an architecture according to one or more of the preceding and/or following examples, wherein the loop filter includes a plurality of integrators, wherein the filtered output includes a plurality of integrator outputs, and wherein each of the plurality of integrator outputs is summed at the second summer to generate the filtered output.

Example 10 provides an architecture according to one or more of the preceding and/or following examples, further comprising a plurality of feedforward paths, each feedforward path from a respective integrator output of the plurality of integrator outputs to the second summer, wherein each of the plurality of feedforward paths includes at least one of a filter and a gain.

Example 11 provides an architecture according to one or more of the preceding and/or following examples, wherein the summed signal is input to the first filter.

Example 12 provides an architecture according to one or more of the preceding and/or following examples, wherein the quantizer is one of a single-bit quantizer and a multi-bit quantizer.

Example 13 provides an architecture according to one or more of the preceding and/or following examples, wherein the quantizer feedback loop includes one of a finite impulse response filter and an infinite impulse response filter.

Example 14 provides an architecture according to one or more of the preceding and/or following examples, wherein the loop filter if further configured to receive the filtered quantized signal generated by the first filter.

Example 15 provides an architecture according to one or more of the preceding and/or following examples, wherein the main feedback loop has an N clock cycle delay, wherein N is an integer.

Example 16 provides a method for a class D modulator, comprising: receiving an input signal; subtracting a feedback signal from the input signal at a summer to generate a summer output; filtering the summer output at a loop filter to generate a filtered output; quantizing the filtered output at a quantizer and outputting a quantized signal; in a main feedback loop: filtering the quantized signal to generate the feedback signal; and feeding back the feedback signal to the summer; wherein filtering the quantized signal and feeding back the feedback signal includes adding a main feedback loop delay, and wherein the main feedback loop delay is one or more clock cycles; and in a quantizer feedback loop: filtering the quantized signal to generate a filtered quantized signal; and feeding back the filtered quantized signal to the quantizer.

Example 17 provides a method according to one or more of the preceding and/or following examples, wherein, in the quantizer feedback loop, filtering the quantized signal includes applying a weight to the quantized signal to generate the filtered quantized signal.

Example 18 provides a method according to one or more of the preceding and/or following examples, wherein, in a second quantizer feedback loop, filtering the quantized signal to generate a second filtered quantized signal, and feeding back the second filtered quantized signal to the quantizer.

Example 19 provides an architecture for a class D modulator, comprising: an input line for receiving an input signal; a summer configured to subtract a feedback signal from the input signal and generate a summer output; a loop filter configured to receive the summer output and produce a filtered output; a quantizer configured to quantize the filtered output and output a quantized signal; and a main feedback loop from the quantizer to the summer configured to filter the quantized signal to generate the feedback signal, wherein the main feedback loop has a delay of one or more clock cycles.

Example 20 provides an architecture according to one or more of the preceding and/or following examples, further comprising a quantizer feedback loop around the quantizer including a first filter, configured to generate a filtered quantized signal, wherein the filtered quantized signal is added back to an input to the quantizer.

Example 21 provides a system including a digital class D modulator including a feedback loop having at least one clock cycle delay.

Example 22 provides a system including a digital class D modulator including a feedback loop around a quantizer.

Example 23 is a system according to one or more of the preceding examples wherein the feedback loop includes a filter.

Example 24 is a system according to one or more of the preceding examples wherein the feedback loop includes a second order filter.

Example 25 is a system according to one or more of the preceding examples wherein the feedback loop includes a third order filter.

Example 26 is a system according to one or more of the preceding examples wherein the feedback loop includes at least two clock cycles delay.

Example 27 is a system according to one or more of the preceding examples, wherein the modulator is one of a 2 level modulator, a 3 level modulator, a 4 level modulator, a 5 level modulator, a 6 level modulator, a 7 level modulator, and an 8 level modulator.

Example 28 is a system according to one or more of the preceding examples, wherein the filter is one of an FIR filter and an IIR filter.

Example 29 provides a system according to one or more of the preceding examples wherein the quantizer is a multibit quantizer.

Example 30 provides a system according to one or more of the preceding examples wherein the quantizer is a single bit quantizer.

Example 31 includes an apparatus that includes a converter as discussed or depicted in any of examples 1-10, some other example, or as otherwise discussed or depicted herein.

Example 32 includes an apparatus comprising means to implement a converter as discussed or depicted in any of examples 1-10, some other example, or as otherwise discussed or depicted herein.

Example 33 includes a method for implementing or manufacturing a converter as discussed or depicted in any of examples 1-10, some other example, or as otherwise discussed or depicted herein.

Example 34 includes one or more non-transitory computer-readable media comprising instructions that, upon execution of the instructions by an electronic device, are to cause the electronic device to implement or manufacture a converter as discussed or depicted in any of examples 1-10, some other example, or as otherwise discussed or depicted herein.

In the preceding discussion, reference may be made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the preceding detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application specific integrated circuit (ASIC), an electronic circuit, a processor (shared, dedicated, or group) or memory (shared, dedicated, or group) that execute one or more software or firmware programs, a combinational logic circuit, or other suitable components that provide the described functionality.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

What is claimed is:

1. An architecture for a class D modulator, comprising:
an input line for receiving an input signal;
a summer configured to subtract a feedback signal from the input signal and generate a summer output;
a loop filter configured to receive the summer output and produce a filtered output;
a quantizer configured to quantize the filtered output and output a quantized signal;
a main feedback loop from the quantizer to the summer configured to filter the quantized signal to generate the feedback signal; and
a quantizer feedback loop around the quantizer including a first filter, configured to generate a filtered quantized signal, wherein the filtered quantized signal is added back into the quantizer.

2. The architecture of claim 1, wherein the quantizer feedback loop includes an amplifier configured to apply a weight to the quantized signal to generate the filtered quantized signal.

3. The architecture of claim 2, wherein the quantizer feedback loop is a first quantizer feedback loop and the filtered quantized signal is a first filtered quantized signal, and further comprising a second quantizer feedback loop in parallel with the first quantizer feedback loop, wherein the second quantizer feedback loop is configured to generate a second filtered quantized signal, and wherein the second filtered quantized signal is added back to the quantizer.

4. The architecture of claim 3, wherein the weight is a first weight and wherein the second quantizer feedback loop includes a second amplifier configured to apply a second weight to the quantized signal to generate the second filtered quantized signal.

5. The architecture of claim 4, wherein the first weight is less than the second weight.

6. The architecture of claim 2, wherein the weight has a value that is less than one, and wherein the filtered quantized signal is smaller than the quantized signal.

7. The architecture of claim 1, further comprising a plurality of quantizer feedback loops around the quantizer.

8. The architecture of claim 1, wherein the summer is a first summer and further comprising a second summer configured to add the filtered output and the filtered quantized signal to generate a summed signal for input to the quantizer.

9. The architecture of claim 8, wherein the loop filter includes a plurality of integrators, wherein the filtered output includes a plurality of integrator outputs, and wherein each of the plurality of integrator outputs is summed at the second summer to generate the filtered output.

10. The architecture of claim 9, further comprising a plurality of feedforward paths, each feedforward path from a respective integrator output of the plurality of integrator outputs to the second summer, wherein each of the plurality of feedforward paths includes at least one of a filter and an amplifier.

11. The architecture of claim 8, wherein the summed signal is input to the first filter.

12. The architecture of claim 1, wherein the quantizer is one of a single-bit quantizer and a multi-bit quantizer.

13. The architecture of claim 1, wherein the quantizer feedback loop includes one of a finite impulse response filter and an infinite impulse response filter.

14. The architecture of claim 1, wherein the loop filter if further configured to receive the filtered quantized signal generated by the first filter.

15. The architecture of claim 1, wherein the main feedback loop has an N clock cycle delay, wherein N is an integer.

16. A method for a class D modulator, comprising:
receiving an input signal;
subtracting a feedback signal from the input signal at a summer to generate a summer output;
filtering the summer output at a loop filter to generate a filtered output;
quantizing the filtered output at a quantizer and outputting a quantized signal;
in a main feedback loop:
filtering the quantized signal to generate the feedback signal; and
feeding back the feedback signal to the summer;
wherein filtering the quantized signal and feeding back the feedback signal includes adding a main feedback loop delay, and wherein the main feedback loop delay is one or more clock cycles; and
in a quantizer feedback loop:
filtering the quantized signal to generate a filtered quantized signal; and
feeding back the filtered quantized signal to the quantizer.

17. The method of claim 16, wherein, in the quantizer feedback loop, filtering the quantized signal includes applying a weight to the quantized signal to generate the filtered quantized signal.

18. The method of claim 16, in a second quantizer feedback loop, filtering the quantized signal to generate a second filtered quantized signal, and feeding back the second filtered quantized signal to the quantizer.

19. An architecture for a class D modulator, comprising:
an input line for receiving an input signal;
a summer configured to subtract a feedback signal from the input signal and generate a summer output;
a loop filter configured to receive the summer output and produce a filtered output;
a quantizer configured to quantize the filtered output and output a quantized signal; and
a main feedback loop from the quantizer to the summer configured to filter the quantized signal to generate the feedback signal, wherein the main feedback loop has a delay of one or more clock cycles.

20. The architecture of claim 19, further comprising a quantizer feedback loop around the quantizer including a first filter, configured to generate a filtered quantized signal, wherein the filtered quantized signal is added back to an input to the quantizer.
